(19) United States
(12) Patent Application Publication
(10) Pub. No.: US 2026/0068086 A1
(43) Pub. Date: Mar. 5, 2026

(54) ELECTRICALLY IMPROVE CONVECTIVE HEAT TRANSFER USING FERROFLUID IN A DIRECT LIQUID COOLING SYSTEM

(71) Applicant: DELL PRODUCTS L.P., Round Rock, TX (US)

(72) Inventors: Bhyrav Mutnury, Round Rock, TX (US); Sandor Farkas, Round Rock, TX (US)

(21) Appl. No.: 18/816,068

(22) Filed: Aug. 27, 2024

(51) Int. Cl. H05K 7/20

(52) U.S. Cl. CPC H05K 7/20272; H05K 7/20254; H05K 7/20263; H05K 7/20772

(57) ABSTRACT

A liquid cooling system includes a tube and a coolant liquid flow motor. The tube carries a liquid coolant. The liquid coolant includes ferromagnetic particles. The coolant liquid flow motor is provided around a perimeter of the tube, and induces a vortex in a flow of the liquid coolant.

### FIELD OF THE DISCLOSURE

This disclosure relates to information handling systems, and more particularly relates to electrically improving convective heat transfer using a ferrofluid in a direct liquid cooling (DLC) system in an information handling system.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A liquid cooling system may include a tube and a coolant liquid flow motor. The tube may carry a liquid coolant. The liquid coolant may include ferromagnetic particles. The coolant liquid flow motor may be provided around a perimeter of the tube, and may induce a vortex in a flow of the liquid coolant.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram of a direct liquid cooling (DLC) system according to an embodiment of the present disclosure;

FIGS. 2A and 2B illustrate a DLC system according to another embodiment of the present disclosure;

FIG. 2C illustrates an input to a coolant liquid flow motor of the DLC system of FIGS. 2A and 2B; and

FIG. 3 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

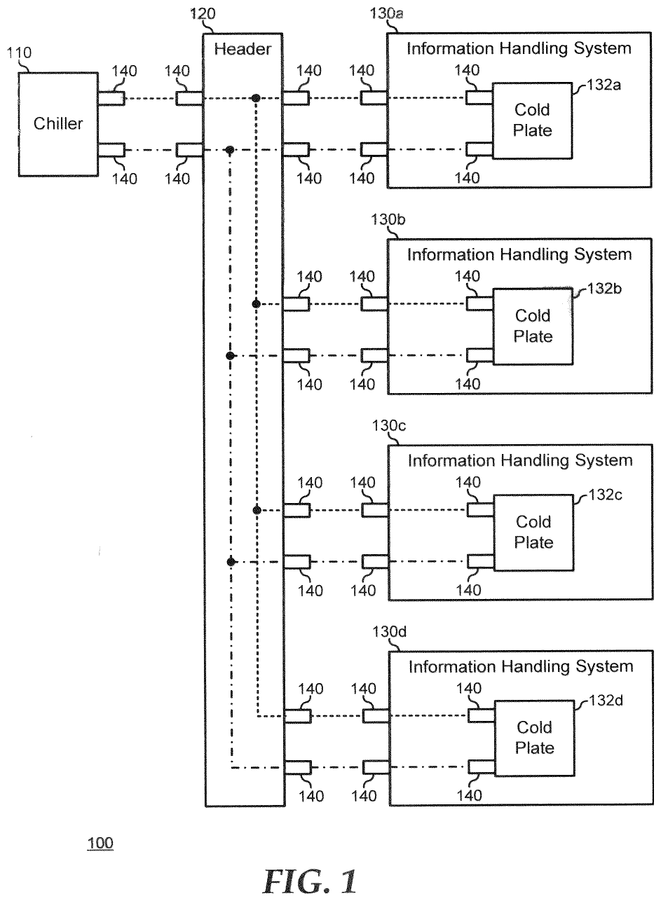

FIG. 1 illustrates a direct liquid cooling (DLC) system 100. DLC system 100 provides cooling for critical components within information handling systems, for example in a data center or other high-density computing environment. DLC system 100 includes a chiller 110, a header 120 and a number of information handling systems 130a-d. Each one of information handling systems 130a-d include one or more components that generate large amounts of heat in the enclosure of their respective information handling systems. For example, information handling systems 130a-d may include one or more processors (CPUs), chipset components, graphics processing units (GPUs), memory devices, storage devices, or the like, that represent a large portion of the thermal load of the respective information handling systems.

In order to remove the heat generated in an information handling system, manufacturers and users are turning to DLC systems like DLC system 100 to more efficiently and effectively manage the heat generated within their information handling systems and data centers. In this regard, information handling systems 130a-d each include one or more cold plate 132a-d to remove the heat from the high-heat generating components. As such, chiller 110 operates to supply chilled coolant liquid (as illustrated by the dotted lines) to header 120. Header 120 includes a cold manifold that distributes the chilled coolant liquid to each of cold plates 132a-d. Cold plates 132a-d are configured to be thermally connected to the high-heat generating components, where the heat from the components is thermally transferred to the coolant liquid. The heated coolant liquid (indicated by the doted/dashed lines) is returned from cold plates 132a-d to header 120 where a cold manifold combines the heated coolant liquid for return to chiller 110. In this regard, DLC system 100 is a closed-loop system, rechilling the coolant liquid for redistribution throughout the DLC system. DLC system 100 is characterized by the need to connect the components together to move the coolant liquid throughout the DLC system. In particular, each component (such as chiller 110, header 120, and cold plates 132a-d includes couplers 140 that couple the respective component to tubing that spans the distance between the respective components.

It has been understood by the inventors of the current disclosure that the coolant liquid flow in a DLC system like DLC system 100 may typically be on the order of 1.5 gallons per minute (GPM) per kilowatt (kW) of heat transferred to the coolant liquid, in order to adequately maintain the cooling of the high-heat generating components. However, a nameplate capacity DLC system that in fact provides 1.5 GPM per kW may nevertheless suffer from various impedances within the DLC system that lowers the actual flow rate to various components. For example, branching of the coolant liquid flow to server multiple components (such as CPU cold plates, DIMMs, etc.), the presence of couplers and various other connectors, or clogging or residue buildup within the DLC system, or other effects may result in the lowering of the coolant liquid flow rate. Such slower coolant liquid flow rates may result in insufficient cooling of the high-heat generating components. In addition, it has been understood that the coolant liquid flow within a DLC system occurs mainly in the middle of the channels (such as through the tubing, couplers, cold plates, or the like), and that the surfaces of the channels experience reduced flow rates of the coolant liquid, due to a boundary layer condition at the inner surface of the channels. Such boundary layer coolant liquid flow rates may be near zero, and thus the ability of the coolant liquid to remove heat from the high-heat generating components may be compromised.

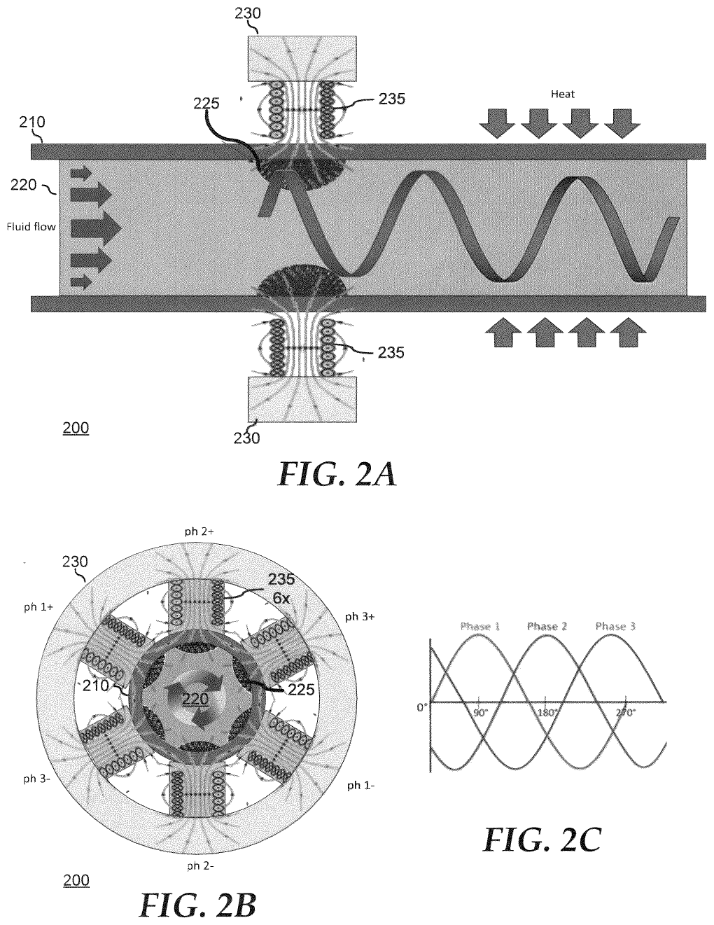

FIGS. 2A and 2B illustrate a DLC system 200 configured to introduce a turbulent flow into the coolant liquid flow to increase the flow rate of coolant liquid 220 at the surface of the channel, in order to improve the convective heat transfer from the high-heat generating component to the coolant liquid. DLC system 200 includes tubing 210 that provides the channel for the flow of coolant liquid 220, and a coolant liquid flow motor 230 that introduces the turbulence into the flow of the coolant liquid. Coolant liquid 220 includes ferromagnetic particles 225 that flow with the coolant liquid. Ferromagnetic particles 225 may be wholly formed of the associated ferromagnetic material, or may be formed as a coating on an underlying structure, such as a polystyrene particle, or the like.

Coolant liquid flow motor 230 includes a coil mounting collar 230 around a perimeter of tubing 210. Coil mounting collar 230 surrounds winding pair 235 made up of two (2) coils. Each coil of winding pair 235 is located opposite each other around the perimeter of tubing 210. Each coil of winding pair 235 is driven by an alternating current (AC) signal to induce a rotating magnetic field within tube 210. As illustrated in FIG. 2B, three (3) winding pairs 235 are each located with a 60 degree offset from each other. An example of a three-phase input to winding pairs 235 is shown in FIG. 2C. The magnetic fields induced into tubing 210 have the effect of attracting ferromagnetic particles 225 to the side walls of the tubing, and to rotate around the inside perimeter of the tubing. The rotation of ferromagnetic particles 225 induces a swirling vortex in coolant liquid 220 downstream of coolant liquid flow motor 230. In this rate, the overall flow rate of coolant liquid 220 in tubing 210 remains constant, but the local velocity of the coolant liquid at the inner perimeter of the tubing is increased due to the vortex. Thus coolant liquid 220 is made to flow faster at the inner perimeter of tubing 210, thereby increasing the heat transfer efficiency of the coolant liquid.

In a particular embodiment, coolant liquid flow motor 230 is placed directly upstream in the flow of coolant liquid 220 from the heat transfer elements of the associated DLC system. For example, a coolant liquid flow motor can be placed at a chilled coolant inlet of a cold-plate assembly for a CPU, a memory device, or the like, to increase the ability of the coolant liquid to remove heat from the high-heat generating components. In another example, a coolant liquid flow motor can be placed at a heated coolant inlet of a chiller assembly for the DLC system to increase the ability of the chiller to remove heat from the coolant liquid. In a particular embodiment, two or more coolant liquid flow motors similar to coolant liquid flow motor 230 are driven by a common set of drive signals to the associated winding pairs 235 of each of the coolant liquid flow motors.

In a particular embodiment, the control of coolant liquid flow motor 230 is provided by a temperature sensing system that provides temperature data to control the operation of the coolant liquid flow motor. For example, when the coolant liquid temperature, or another temperature such as a device temperature, is below a particular threshold temperature, the control current to coolant liquid flow motor 230 may be shut off, to save power in the information handling system. Then, when the coolant/device temperature exceeds the threshold temperature, the control current may be turned on to improve the heat transfer efficiency. In a particular case, a speed of the rotation of the coolant liquid may depend on how high the coolant/device temperature is above the threshold temperature. For example, as the coolant/device temperature increases, the speed of the rotation can likewise be increased.

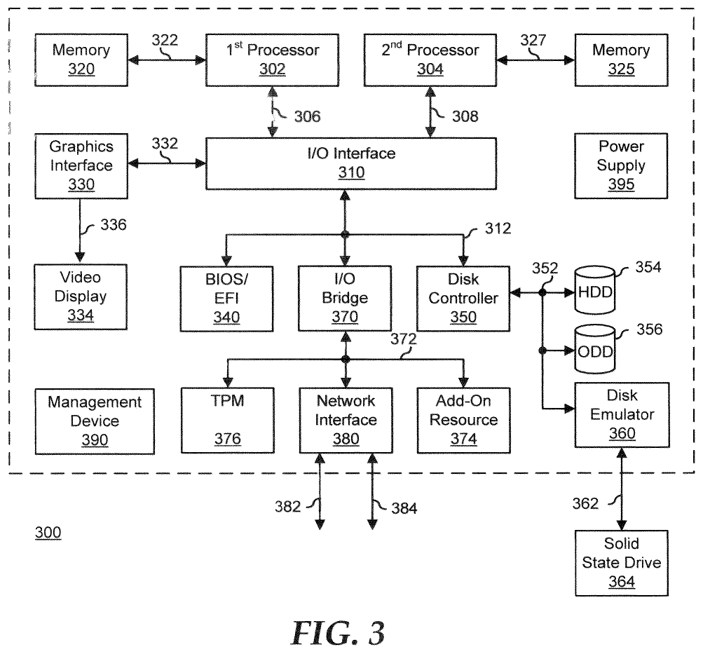

FIG. 3 illustrates a generalized embodiment of an information handling system 300 similar to information handling system 300. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 300 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 300 can include processing resources for executing machine-executable code, such as a central processing unit (CPU), a programmable logic array (PLA), an embedded device such as a System-on-a-Chip (SoC), or other control logic hardware. Information handling system 300 can also include one or more computer-readable medium for storing machine-executable code, such as software or data. Additional components of information handling system 300 can include one or more storage devices that can store machine-executable code, one or more communications ports for communicating with external devices, and various input and output (I/O) devices, such as a keyboard, a mouse, and a video display. Information handling system 300 can also include one or more buses operable to transmit information between the various hardware components.

Information handling system 300 can include devices or modules that embody one or more of the devices or modules described below, and operates to perform one or more of the methods described below. Information handling system 300 includes a processors 302 and 304, an input/output (I/O) interface 310, memories 320 and 325, a graphics interface 330, a basic input and output system/universal extensible firmware interface (BIOS/UEFI) module 340, a disk controller 350, a hard disk drive (HDD) 354, an optical disk drive (ODD) 356, a disk emulator 360 connected to an external solid state drive (SSD) 362, an I/O bridge 370, one or more add-on resources 374, a trusted platform module (TPM) 376, a network interface 380, a management device 390, and a power supply 395. Processors 302 and 304, I/O interface 310, memory 320, graphics interface 330, BIOS/UEFI module 340, disk controller 350, HDD 354, ODD 356, disk emulator 360, SSD 362, I/O bridge 370, add-on resources 374, TPM 376, and network interface 380 operate together to provide a host environment of information handling system 300 that operates to provide the data processing functionality of the information handling system. The host environment operates to execute machine-executable code, including platform BIOS/UEFI code, device firmware, operating system code, applications, programs, and the like, to perform the data processing tasks associated with information handling system 300.

In the host environment, processor 302 is connected to I/O interface 310 via processor interface 306, and processor 304 is connected to the I/O interface via processor interface 308. Memory 320 is connected to processor 302 via a memory interface 322. Memory 325 is connected to processor 304 via a memory interface 327. Graphics interface 330 is connected to I/O interface 310 via a graphics interface 332, and provides a video display output 336 to a video display 334. In a particular embodiment, information handling system 300 includes separate memories that are dedicated to each of processors 302 and 304 via separate memory interfaces. An example of memories 320 and 330 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 340, disk controller 350, and I/O bridge 370 are connected to I/O interface 310 via an I/O channel 312. An example of I/O channel 312 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 310 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 340 includes BIOS/UEFI code operable to detect resources within information handling system 300, to provide drivers for the resources, initialize the resources, and access the resources. BIOS/UEFI module 340 includes code that operates to detect resources within information handling system 300, to provide drivers for the resources, to initialize the resources, and to access the resources.

Disk controller 350 includes a disk interface 352 that connects the disk controller to HDD 354, to ODD 356, and to disk emulator 360. An example of disk interface 352 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 360 permits SSD 364 to be connected to information handling system 300 via an external interface 362. An example of external interface 362 includes a USB interface, an IEEE 1394 (Firewire) interface, a proprietary interface, or a combination thereof. Alternatively, solid-state drive 364 can be disposed within information handling system 300.

I/O bridge 370 includes a peripheral interface 372 that connects the I/O bridge to add-on resource 374, to TPM 376, and to network interface 380. Peripheral interface 372 can be the same type of interface as I/O channel 312, or can be a different type of interface. As such, I/O bridge 370 extends the capacity of I/O channel 312 where peripheral interface 372 and the I/O channel are of the same type, and the I/O bridge translates information from a format suitable to the I/O channel to a format suitable to the peripheral channel 372 where they are of a different type. Add-on resource 374 can include a data storage system, an additional graphics interface, a network interface card (NIC), a sound/video processing card, another add-on resource, or a combination thereof. Add-on resource 374 can be on a main circuit board, on separate circuit board or add-in card disposed within information handling system 300, a device that is external to the information handling system, or a combination thereof.

Network interface 380 represents a NIC disposed within information handling system 300, on a main circuit board of the information handling system, integrated onto another component such as I/O interface 310, in another suitable location, or a combination thereof. Network interface device 380 includes network channels 382 and 384 that provide interfaces to devices that are external to information handling system 300. In a particular embodiment, network channels 382 and 384 are of a different type than peripheral channel 372 and network interface 380 translates information from a format suitable to the peripheral channel to a format suitable to external devices. An example of network channels 382 and 384 includes InfiniBand channels, Fibre Channel channels, Gigabit Ethernet channels, proprietary channel architectures, or a combination thereof. Network channels 382 and 384 can be connected to external network resources (not illustrated). The network resource can include another information handling system, a data storage system, another network, a grid management system, another suitable resource, or a combination thereof.

Management device 390 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 300. In particular, management device 390 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 300, such as system cooling fans and power supplies. Management device 390 can include a network connection to an external management system, and the management device can communicate with the management system to report status information for information handling system 300, to receive BIOS/UEFI or system firmware updates, or to perform other task for managing and controlling the operation of information handling system 300. Management device 390 can operate off of a separate power plane from the components of the host environment so that the management device receives power to manage information handling system 300 where the information handling system is otherwise shut down. An example of management device 390 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 390 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed:

1. A liquid cooling system, comprising:
a tube to carry a liquid coolant, the liquid coolant including ferromagnetic particles; and
a coolant liquid flow motor around a perimeter of the tube, the coolant liquid flow motor to induce a vortex in a flow of the liquid coolant.

2. The liquid cooling system of claim 1, wherein the coolant liquid flow motor includes a collar surrounding the perimeter of the tube.

3. The liquid cooling system of claim 2, wherein the coolant liquid flow motor includes a winding pair.

4. The liquid cooling system of claim 3, wherein the winding pair includes a pair of wire windings.

5. The liquid cooling system of claim 4, wherein each wire winding of the winding pair is driven by an alternating current signal.

6. The liquid cooling system of claim 5, wherein the alternating current signal induces a rotating magnetic field in the tube.

7. The liquid cooling system of claim 6, wherein the rotating magnetic field interacts with the ferromagnetic particles to rotate the ferromagnetic particles.

8. The liquid cooling system of claim 3, wherein the coolant liquid flow motor includes at least one additional winding pair.

9. The liquid cooling system of claim 8, wherein the coolant liquid flow motor includes two additional winding pairs.

10. The liquid cooling system of claim 1, further comprising:
a heat exchanging element, wherein the coolant liquid flow motor is upstream from the heat exchanging element in a flow of the coolant liquid.

11. A method, comprising:
providing, in a liquid cooling system, a tube to carry a liquid coolant that includes ferromagnetic particles;
providing a coolant liquid flow motor around the tube; and
inducing, by the coolant liquid flow motor, a vortex in a flow of the liquid coolant.

12. The method of claim 11, further comprising providing, in the coolant liquid flow motor, a collar surrounding the perimeter of the tube.

13. The method of claim 12, further comprising providing, in the coolant liquid flow motor, a winding pair.

14. The method of claim 13, further comprising providing, in the winding pair, a pair of wire windings.

15. The method of claim 14, further comprising driving each wire winding of the winding pair by an alternating current signal.

16. The method of claim 15, wherein the alternating current signal induces a rotating magnetic field in the tube.

17. The method of claim 16, wherein the rotating magnetic field interacts with the ferromagnetic particles to rotate the ferromagnetic particles.

18. The method of claim 13, further comprising, providing, in the coolant liquid flow motor, at least one additional winding pair.

19. The method of claim 18, wherein the coolant liquid flow motor includes two additional winding pairs.

20. An information handling system, comprising:
a heat generating component; and
a liquid cooling system to remove heat from the heat generating component, the liquid cooling system including:
a tube to carry a liquid coolant having ferromagnetic particles; and
a coolant liquid flow motor around the tube, the coolant liquid flow motor to induce a vortex in a flow of the liquid coolant.
